(19) United States
(12) Patent Application Publication
(10) Pub. No.: US 2026/0119739 A1
(43) Pub. Date: Apr. 30, 2026

(54) DEVICE AND COMPUTER-IMPLEMENTED METHOD FOR TESTING A TECHNICAL SYSTEM, IN PARTICULAR A SYSTEM FOR DETERMINING A VIRTUAL SENSOR SIGNAL

(71) Applicant: Robert Bosch GmbH, Stuttgart (DE)

(72) Inventors: Thomas Spieker, Weissach (DE); David Reeb, Renningen (DE); Stefan Aulbach, Renningen (DE)

(21) Appl. No.: 19/352,104

(22) Filed: Oct. 7, 2025

(30) Foreign Application Priority Data
Oct. 24, 2024 (DE) 10 2024 210 283.0

(51) Int. Cl. G06F 30/20

(52) U.S. Cl. CPC G06F 30/20

(57) ABSTRACT

A device and computer-implemented method for testing a technical system. The system includes a model that models a physical process. In the physical process, a physical input variable of the physical process leads to a physical output variable of the physical process. An input space includes input values of the physical input variable. An output space includes output values of the physical output variable. A surrogate model is provided for the model, which is configured to describe the real physical process. Input values are recorded. Simplexes spanned by the recorded input values are determined in the input space. For each simplex, at least one input value from the input space is determined, in a human-machine interaction with a user, or is randomly drawn on the simplex according to a predetermined probability distribution. The output value for the input value is determined using the surrogate model.

### FIELD

The present invention relates to a device and a computer-implemented method for testing a technical system, in particular a system for determining a virtual sensor signal.

### BACKGROUND INFORMATION

Solutions that enable the use of artificial neural networks in safety-relevant production are of great interest.

### SUMMARY

The computer-implemented method is provided for testing a technical system, in particular a system for determining a virtual sensor signal, for example of a virtual sensor. According to an example embodiment of the present invention, the method provides that the system comprises a model that models a physical process, wherein, in the physical process, a physical input variable of the physical process leads to a physical output variable of the physical process, wherein an input space comprises input values of the physical input variable, wherein an output space comprises output values of the physical output variable, wherein a surrogate model is provided for the model, the surrogate model being designed to describe the real physical process, wherein input values are recorded, wherein simplexes spanned by the recorded input values are determined in the input space, wherein, for each simplex, at least one input value from the input space is determined, in particular in a human-machine interaction with a user, or is randomly drawn on the simplex according to a predetermined probability distribution, in particular a uniform distribution, the output value for the input value is determined using the surrogate model, the input value is mapped with the model to a prediction for the output value, in particular for determining the virtual sensor signal, and a distance between the prediction and the output value is determined, wherein a result of the test comprises a probability that the model maps an input value of the physical input variable from the input space to a prediction that deviates from an output value of the physical output variable of the physical process for the physical input variable with the input value, in particular by more than a predetermined deviation. This allows regions defined by the simplexes in the input space of the system to be qualitatively evaluated. In this case, input values in the input space are recorded, i.e., data points, e.g., training data, from which the simplexes can be spanned.

The model may include a machine learning prediction function, such as an artificial neural network or a Gaussian process.

According to an example embodiment of the present invention, it may be provided that the distance is determined depending on an amount of a difference between the prediction and the output value.

According to an example embodiment of the present invention, it may be provided that the probability is determined depending on a ratio of the number of distances greater than a tolerance to a number of distances determined during testing. This makes evaluation possible when there are distances outside the tolerance.

According to an example embodiment of the present invention, it may be provided that the probability is determined using a generalized Pareto distribution, the generalized Pareto distribution being adjusted to distances determined for the simplexes that are smaller than a tolerance. This makes the evaluation possible if there are no distances outside the tolerance.

It can be provided that it is checked, during testing, whether at least one distance has been determined which is greater than the tolerance, the probability being determined depending on the ratio if at least one distance is greater than the tolerance, otherwise the probability being determined using the generalized Pareto distribution.

It can be provided that the surrogate model is designed to describe the real physical process with a tolerance, the tolerance being determined depending on a tolerable deviation, in particular as a fraction of the deviation, for example as half of the deviation. This adjusts the evaluation to the tolerances.

It can be provided that the probability is determined with the same tolerance for the simplexes, in particular in a temporally overlapping or simultaneous manner, or that the probability is determined with different tolerances for at least two simplexes. Using the same tolerance allows for rapid evaluation. The different tolerances provide an adaptation of the tolerable deviations to the regions of the input space.

For example, multiple distances are determined for each simplex, for example for different input values. This increases the meaningfulness of the probability.

According to an example embodiment of the present invention, it can be provided that the model is trained on a measured training data set which comprises pairs of input values from the input space and output values from the output space, wherein, if the probability for at least one simplex is greater than a predetermined limit, new training data, in particular with input values from the simplex or the simplexes which have a probability greater than the limit, are measured and added to the training data set, and the model is trained on the training data set supplemented with the training data, or that the model is authorized for the reliable prediction of the physical process if no probability for any simplex is greater than a predetermined limit.

According to an example embodiment of the present invention, a device for testing a system, in particular a system for determining a virtual sensor signal, for example of a virtual sensor, provides that the device comprises at least one processor and at least one memory, the at least one processor being designed to execute instructions stored in the memory, upon execution of which instructions by the at least one processor the device carries out the method of the present invention.

According to an example embodiment of the present invention, a computer program can be provided, the computer program comprising instructions executable by a computer, upon the execution of which by the computer the method of the present invention takes place.

Further advantageous embodiments can be found in the following description and the figures.

### BRIEF DESCRIPTION OF THE DRAWINGS

FIG. 1 is a schematic view of a device for testing, according to an example embodiment of the present invention.

FIG. 2 is a flow chart with steps of a method for testing, according to an example embodiment of the present invention.

FIG. 3 is a schematic view of an input space, according to an example embodiment of the present invention.

FIG. 4 is a schematic view of output values of a model for determining the output values of the physical process, according to an example embodiment of the present invention.

FIG. 5 is a schematic representation of a histogram of distances of a prediction from output values, according to an example embodiment of the present invention.

### DETAILED DESCRIPTION OF EXAMPLE EMBODIMENTS

FIG. 1 schematically shows a device 100.

The device 100 comprises at least one processor 102, at least one memory 104. The device 100 is designed to test a technical system 106. In the example, the technical system 106 is arranged in the device 100 for testing. The technical system 106 can also be arranged outside the device 100 for testing.

The technical system 106 is, for example, a system for determining a virtual sensor signal. The technical system 106 is for example a virtual sensor.

The technical system 106 comprises a model. The model includes e.g. a machine learning function, e.g. an artificial neural network f or a Gaussian process. The technical system 106 is designed to record input values 108 from a machine 110. The machine 110 is, for example, an internal combustion engine or an electric machine.

The at least one processor 102 is configured to execute instructions stored in the memory 104, upon execution of which instructions by the at least one processor 102 the device 100 executes a method for testing the technical system 106.

For example, the model is designed to predict an output value to determine a virtual sensor signal.

The technical system 106 is designed, for example, to determine and output the virtual sensor signal depending on the prediction.

It can be provided that the technical system 106 is designed for human-machine interaction with a user.

It can be provided that the input variable 108 is one-dimensional or multi-dimensional.

The device 100 for testing the technical system 106 is e.g. connected to a test bench. The test bench is designed to specifically measure a real existing physical system. The test bench is designed to determine the output values of the physical process running on the physical system for input values from a given range in the input space, in particular for simplexes, in particular for given input values. The test bench is designed to specifically generate new pairs of input and output values. The test bench is designed, for example, to record the pairs for an extension of a data set, e.g. a training data set, which is required for testing the technical system 106.

The device 100 for testing the technical system 106 is designed, for example, to carry out the test in machine learning (ML) according to the following sequence:

1. Training the model, e.g. the ML function, on a measured training data set that includes pairs of input values from the input space and output values from the output space. The model is represented e.g. by the artificial neural network f or the Gaussian process.

2. Testing the model using the method.

The output of the method is the probability that the model makes predictions with a large deviation from the expected physical output value—and specifically for each individual simplex.

3. Repeating the test.

If the probability for at least one simplex is greater than a previously defined limit p*, the test bench requests new training data, in particular with input values from the simplexes that have a probability p>p*. These new training data are added to the existing training data set and steps 1 and 2 are repeated.

4. Authorizing the model.

If no probability for any simplex is greater than the limit p*, the model is authorized for the reliable prediction of the physical process.

5. Termination criterion.

If step 4 is not achieved, e.g. after a specified time on the test bench, or if the training data set reaches or exceeds a specified size, the tested model is discarded and another model is tested.

The other model has e.g. an alternative architecture of the model. In the neural network, for example more neurons are provided in the neural network f. In the Gaussian process, for example a different core is provided in the Gaussian process.

The other model uses for example an alternative input variable or alternative input variables.

The sequence is then started again with the other model.

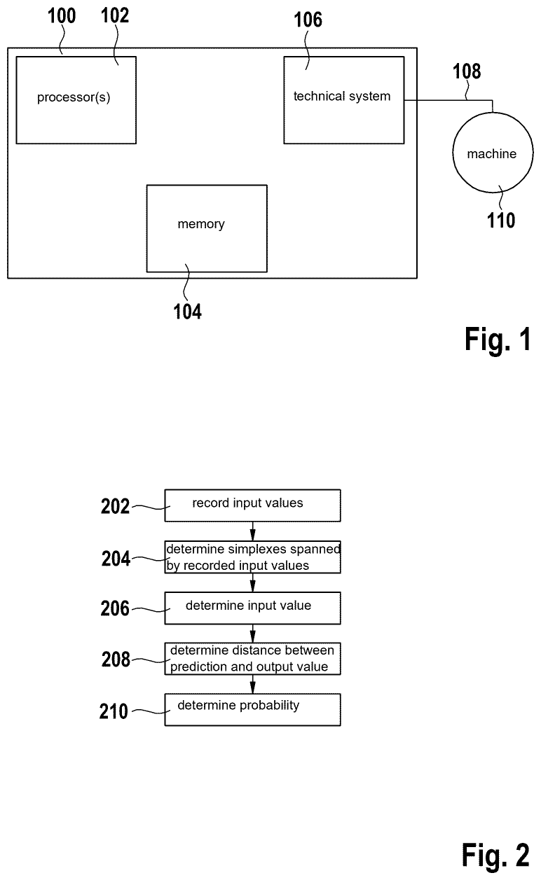

FIG. 2 is a flow chart with steps of the method by way of example. The method is explained below using the example of the artificial neural network f and is applied accordingly to another model, e.g. the model with the Gaussian process.

The artificial neural network f models a physical process g:X→Y.

In the physical process, a physical input variable x∈X of the physical process g from an input space X of the physical process leads to a physical output variable y∈Y of the physical process in an output space Y of the physical process.

The input space X includes input values of the physical input variable x. The output space Y includes output values of the physical output variable y.

The artificial neural network f maps an input value of the physical input variable x on the prediction ƒ(x) for an output value of the physical output variable y.

The input variable 108 is an example of the physical input variable x. The virtual consumption is an example of the physical output variable y.

For testing, a surrogate model for the model is provided, i.e. in the example for the artificial neural network f. In the example, the surrogate model is a function h: X→Y.

The surrogate model h is designed to describe the real physical process g. For example, the function is designed to describe the real physical process with a tolerance ϵ/2.

The method comprises a step 202.

In step 202, input values are recorded.

The method comprises a step 204.

In step 204, simplexes spanned by the recorded input values are determined in the input space X.

A one-dimensional simplex S is spanned e.g. by two recorded input values as follows:

$$x ( {λ}_{i j} ) = {λ}_{i j} {x}_{j} + ( 1 + {λ}_{i j} ) {x}_{i} where {λ}_{i j} ∈ [ 0 , 1 ]$$

For the provided surrogate model h the following applies:

$$∀ {λ}_{i j} ∈ [ 0 , 1 ] \vert \vert g ( x ( {λ}_{i j} ) ) - h ( x ( {λ}_{i j} ) ) \vert < ϵ / 2$$

This means that the surrogate model h describes the real physical process g within all simplexes well, i.e. with a tolerance that is defined by ϵ.

The method comprises a step 206.

In step 206, for each simplex
a) at least one input value xₖ is determined from the input space or drawn at random,
b) with the surrogate model h the output value h(xₖ) is determined for the input value xₖ′
c) the input value xₖ is mapped with the artificial neural network f to a prediction for the output value.

The particular input value xₖ is determined e.g. in human-machine interaction with the user.

The particular input value xₖ is randomly drawn, e.g. according to a given probability distribution U(S), in particular a uniform distribution, on the simplex xₖ˜U(S).

The method comprises a step 208.

In step 208, a distance dₖ between the prediction ƒ(xₖ) and the output value of the surrogate model h(xₖ) is determined for each prediction.

The distance is determined e.g. depending on an amount of a difference between the prediction and the output value, e.g. dₖ=|ƒ(xₖ)−h(xₖ)|.

It can be provided that for each simplex multiple distances for different input values xₖ are determined.

The method comprises a step 210.

In step 210, a probability p that the artificial neural network f maps an input value of the physical input variable from the input space to a prediction that deviates from an output value of the physical output variable of the physical process for the physical input variable with the input value, in particular by more than a predefined deviation, e.g. ϵ/2 is determined, depending on the N distances dₖ determined for the simplex or for the simplexes.

For example, a test result includes the probability.

The probability p is determined for example depending on a ratio of the distances greater than a tolerance to a number of distances determined during testing:

$$p = \frac{\vert \{ {d}_{k} \vert {d}_{k} > \frac{ϵ}{2} \} \vert}{N}$$

The probability p is determined e.g. using a generalized Pareto distribution with a density function γ, the generalized Pareto distribution being adapted to distances determined for the simplexes that are smaller than a tolerance.

$$p = {\int }_{\frac{ϵ}{2}}^{∞} γ ( x ) d x$$

For example, the tolerance is determined depending on the deviation ϵ. It may be provided that the tolerance is determined as a fraction of the deviation ϵ. For example, the tolerance is determined as half of the deviation, i.e. ϵ/2.

It may be provided that during testing it is checked whether at least one distance has been determined that is greater than the tolerance. The probability is determined for example depending on the ratio if at least one distance is greater than the tolerance. Otherwise, the probability is determined for example using the generalized Pareto distribution.

The method may provide that the probability is determined with the same tolerance for the simplexes. For example, the probability for the simplexes is determined in a temporally overlapping or simultaneous manner.

The method may provide that the probability is determined with different tolerances for at least two simplexes.

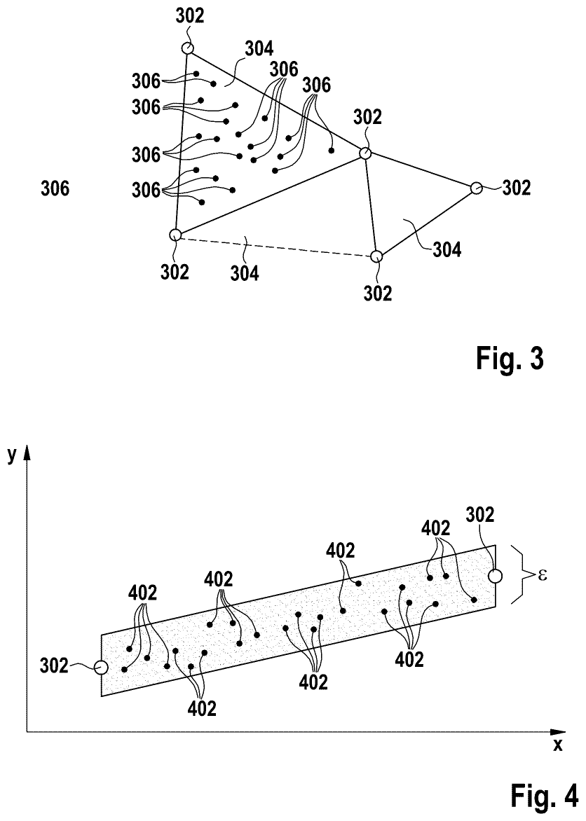

FIG. 3 schematically shows an input space by way of example.

The input space contains recorded input values 302. The recorded input values 302 are for example the result of measurements of the input variable 108 on the machine 110.

FIG. 3 shows the simplexes 304. The example shows three simplexes.

In FIG. 3, input values 306 determined or drawn during testing are shown by way of example in one of the simplexes 304.

In FIG. 4, for an exemplary one-dimensional simplex spanned by two exemplary input values 302, a schematic representation of exemplary output values y=ƒ(x) determined using the function ƒ for exemplary input values x from the one-dimensional simplex is shown, and is denoted in FIG. 4 by reference sign 402. In the example, the output values y are within the tolerance ϵ/2. This means that the absolute distance both upward and downward is smaller than ϵ/2.

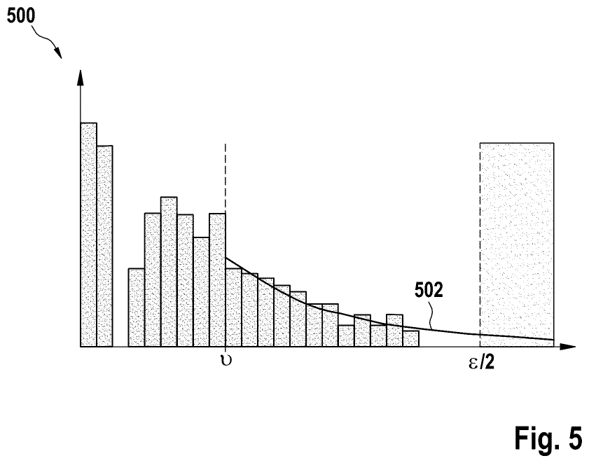

FIG. 5 schematically shows a histogram 500 of distances between the prediction of the artificial neural network and the output values of the function.

Beyond a limit u a generalized Pareto distribution 502 is shown. The generalized Pareto distribution 502 is adapted to the distances determined for the simplexes which are smaller than the tolerance ϵ/2 and greater than the limit u.

An exemplary embodiment concerns the surrogate model h which is provided and which is designed to describe the real physical process.

The surrogate model h is formed for example by determining, on each of the simplexes, the linear interpolation of measured output values yₖ which belong to the input values xₖ from step 202.

If a single or a given simplex is spanned by the input values x₁,x₂, . . . , xₛ and therefore any point x=λ₁*x₁+λ2*x₂+ . . . +λₛ*xₛ rom this simplex is given, the coefficients λ₁, λ₂, . . . , λₛ being non-negative real numbers that sum to 1, then the surrogate model h is defined as h(x)=λ₁*y₁+λ₂*y₂+ . . . +λₛ*yₛ, wherein y₁, y₂, . . . yₛ are the physically measured output values belonging to the input values x₁, x₂, . . . , xₛ.

Another surrogate model h can also be used, e.g. a Gaussian process or a physical model.

1-11. (canceled)

12. A computer-implemented method for testing a technical system for determining a virtual sensor signal of a virtual sensor, wherein the system includes a model that models a physical process, wherein, in the physical process, a physical input variable of the physical process leads to a physical output variable of the physical process, wherein an input space includes input values of the physical input variable, wherein an output space includes output values of the physical output variable, the method comprising the following steps:
providing a surrogate model for the model, the surrogate model being configured to describe the real physical process;
recording input values;
determining simplexes spanned by the recorded input values in the input space;
for each of the simplexes:
(i) determining at least one input value from the input space in a human-machine interaction with a user, or (ii) randomly drawing the input value according to a predetermined probability distribution on the simplex,
determining an output value for the input value using the surrogate model, and
mapping the input value with the model to a prediction for the output value for determining the virtual sensor signal,
determining, for each of the predictions, a distance between the prediction for the output and the output value; and
determining, as a result of the test, a probability that the model maps an input value of the physical input from the input space to a prediction which deviates from an output value of the physical output variable of the physical process for the physical input variable with the input value, by more than a predetermined deviation.

13. The method according to claim 12, wherein each distance is determined depending on an amount of a difference between the prediction and the output value.

14. The method according to claim 12, wherein the probability is determined depending on a ratio of a number of the distances which are greater than a tolerance to a number of distances determined during testing.

15. The method according to claim 12, wherein the probability is determined using a generalized Pareto distribution, the generalized Pareto distribution being adapted to the distances determined for the simplexes which are smaller than a tolerance.

16. The method according to claim 15, wherein, during testing, it is checked whether at least one distance has been determined which is greater than the tolerance, the probability being determined depending on the ratio when at least one distance is greater than the tolerance, otherwise the probability is determined using the generalized Pareto distribution.

17. The method according to claim 14, wherein the surrogate model is configured to describe the real physical process with a tolerance, the tolerance being determined depending on a tolerable deviation as a fraction of the tolerable deviation.

18. The method according to claim 17, wherein: (i) the probability is determined with the same tolerance for the simplexes, in a temporally overlapping or simultaneous manner, or (ii) the probability is determined with different tolerances for at least two simplexes.

19. The method according to claim 12, wherein multiple distances are determined for each simplex, for different input values.

20. The method according to claim 12, wherein the model is trained on a measured training data set which includes pairs of input values from the input space and output values from the output space, wherein: (i) when the probability for at least one simplex is greater than a predetermined limit, new training data, with input values from the simplexes which have a probability greater than the limit, are measured and added to the training data set, and the model is trained on the training data set supplemented with the training data, or (ii) the model is authorized for reliable prediction of the physical process when no probability for any simplex is greater than a predetermined limit.

21. A device for testing a technical system for determining a virtual sensor signal of a virtual sensor, the device comprising:
at least one processor; and
at least one non-transitory memory;
wherein the at least one processor is configured to execute instructions stored on the memory, and upon execution of the instructions by the at least one processor, the device configured to performing a method for testing the technical system, wherein the system includes a model that models a physical process, wherein, in the physical process, a physical input variable of the physical process leads to a physical output variable of the physical process, wherein an input space includes input values of the physical input variable, wherein an output space includes output values of the physical output variable, the method comprising the following steps:
providing a surrogate model for the model, the surrogate model being configured to describe the real physical process;
recording input values;
determining simplexes spanned by the recorded input values in the input space;
for each of the simplexes:
(i) determining at least one input value from the input space in a human-machine interaction with a user, or (ii) randomly drawing the input value according to a predetermined probability distribution on the simplex,
determining an output value for the input value using the surrogate model, and
mapping the input value with the model to a prediction for the output value for determining the virtual sensor signal,
determining, for each of the predictions, a distance between the prediction for the output and the output value; and
determining, as a result of the test, a probability that the model maps an input value of the physical input from the input space to a prediction which deviates from an output value of the physical output variable of the physical process for the physical input variable with the input value, by more than a predetermined deviation.

22. A non-transitory computer-readable medium on which is stored a computer program including instructions for testing a technical system for determining a virtual sensor signal of a virtual sensor, wherein the system includes a model that models a physical process, wherein, in the physical process, a physical input variable of the physical process leads to a physical output variable of the physical process, wherein an input space includes input values of the physical input variable, wherein an output space includes output values of the physical output variable, the instructions, when executed by a computer, causing the computer to perform the steps comprising:
providing a surrogate model for the model, the surrogate model being configured to describe the real physical process;
recording input values;
determining simplexes spanned by the recorded input values in the input space;
for each of the simplexes:
(i) determining at least one input value from the input space in a human-machine interaction with a user, or (ii) randomly drawing the input value according to a predetermined probability distribution on the simplex,
determining an output value for the input value using the surrogate model, and
mapping the input value with the model to a prediction for the output value for determining the virtual sensor signal,
determining, for each of the predictions, a distance between the prediction for the output and the output value; and
determining, as a result of the test, a probability that the model maps an input value of the physical input from the input space to a prediction which deviates from an output value of the physical output variable of the physical process for the physical input variable with the input value, by more than a predetermined deviation.
